(19) United States
(12) Patent Application Publication
(10) Pub. No.: US 2023/0409784 A1
(43) Pub. Date: Dec. 21, 2023

(54) EXCIMER LASER ENERGY MODEL IDENTIFICATION METHOD AND APPARATUS

(71) Applicant: BEIJING RSLASER OPTO-ELECTRONICS TECHNOLOGY CO., LTD., Beijing (CN)

(72) Inventors: Zebin FENG, Beijing (CN); Sai LIANG, Beijing (CN); Xiangyu XU, Beijing (CN); Rui JIANG, Beijing (CN); Guangyi LIU, Beijing (CN); Bin LIU, Beijing (CN); Pei CAO, Beijing (CN)

(73) Assignee: BEIJING RSLASER OPTO-ELECTRONICS TECHNOLOGY CO., LTD., Beijing, BJ (CN)

(21) Appl. No.: 18/459,424

(22) Filed: Sep. 1, 2023

Related U.S. Application Data
(63) Continuation of application No. PCT/CN2021/112947, filed on Aug. 17, 2021.

(30) Foreign Application Priority Data
Mar. 1, 2021 (CN) 202110224539.5

(51) Int. Cl. G06F 30/27

(52) U.S. Cl. CPC G06F 30/27

(57) ABSTRACT

Disclosed in the present invention are an excimer laser energy model identification method and apparatus. The method comprises the following steps: establishing a gated recurrent network for excimer laser energy model identification; within a plurality of preset time periods, setting energy collection conditions in a single laser pulse mode, and collecting a training data set for excimer laser energy model identification; and using the training data set to train the established gated recurrent network, and when a training termination condition is satisfied, ending the training and obtaining an excimer laser energy model. By means of the method provided by the present invention, the maximum error between a pulse energy generated by the identified excimer laser energy model and an actual pulse energy is less than 1.5%, and thus, a simulation requirement of excimer laser energy characteristic control can be met.

### BACKGROUND

### Technical Field

The present invention relates to a laser energy model identification method, particularly relates to an excimer laser energy model identification method based on a gated recurrent unit network, also relates to a corresponding excimer laser energy model identification apparatus, and belongs to the technical field of laser.

### Related Art

With the rapid development of laser technology, the laser technology is widely applied to each field. Excimer lasers are widely applied to the fields such as industry, medical treatment and scientific research with features of short wavelength, high power, narrow linewidths, etc. Particularly, rare gas halide excimer lasers become the most important laser light sources of a semiconductor photoetching industry at present with its characteristics of high peak power of output laser, great single pulse energy, wavelength in an ultraviolet band, etc. The energy characteristic of the excimer lasers is one of three major key indexes (energy, linewidth and wavelength) of photoetching excimer lasers, and directly determines the machining accuracy, yield and the critical size of semiconductor photoetching machines. Therefore, building an excimer laser energy model (i.e., an excimer laser output beam energy model) is a basis for studying and controlling the laser energy characteristic.

During the study on the excimer laser output beam energy, the adopted excimer laser energy model much closer to actual output beam energy rule is more conducive to the study. However, the excimer laser energy model is a complicated nonlinear model, and it is difficult to obtain a precise model through theoretical derivation.

### SUMMARY

The first technical problem to be solved by the present invention is to provide an excimer laser energy model identification method.

The other technical problem to be solved by the present invention is to provide an excimer laser energy model identification apparatus.

In order to achieve the above purposes, the present invention adopts the following technical solution:

According to the first aspect of embodiments of the present invention, an excimer laser energy model identification method is provided, and includes the following steps:

Step S1: building a gated recurrent unit network for excimer laser energy model identification;

Step S2: setting energy harvesting conditions in a single laser pulse manner in a plurality of preset moments to harvest a training dataset for excimer laser energy model identification; and

Step S3: training the built gated recurrent unit network by using the training dataset, and ending the training to obtain an excimer laser energy model when reaching a training ending condition.

Preferentially, the gated recurrent unit network includes gated recurrent units corresponding to a plurality of time sequences, each of the gated recurrent units includes an input layer, a hidden layer and an output layer, the input layer is connected with the hidden layer, the hidden layer is connected with the output layer, and the hidden layers of the adjacent gated recurrent units are connected.

Preferentially, the energy harvesting conditions refer to the time interval of single laser pulses and a discharge high voltage value, and the time interval of the single laser pulses refers to the time interval from a current laser pulse to a former laser pulse.

Preferentially, the hidden layer of each of the gated recurrent units includes a reset gate r(t), a refresh gate z(t) and a candidate hidden layer state h(t);

the refresh gate z(t) represents the information amount brought by the state of a former moment to a current moment, and is shown by:

z(t)=σ(W_{z}·x(t)+U_{z}·h(t−1))

in the formula, σ represents an activation function, the activation function is a sigmoid function, W_{z} represents an input weight matrix of the refresh gate, x(t) represents an input variable of the current gated recurrent unit network, U_{z} represents a transfer matrix of the hidden layer state of the refresh gate, and h(t−1) represents a hidden layer state of a former moment;

the reset gate r(t) represents a degree of the current state ignoring the former moment state, and is shown by:

r(t)=σ(Wᵣ·x(t)+Uᵣ·h(t−1))

in the formula, Wᵣ represents an input weight matrix of the reset gate, and Uᵣ represents a transfer matrix of the hidden layer state of the reset gate;

the candidate hidden layer state h̅(t) is used for assisting the calculation of the hidden layer state h(t), and is shown by:

h̅(t)=tan h(W·x(t)+U·(r(t)⊙h(t−1)))

in the formula, W represents an input weight matrix of the candidate hidden layer state, U represents a transfer matrix of the candidate hidden layer state aiming at the hidden layer state of a former moment, and ⊙ represents a Hadamard product; and the hidden layer state h(t) of the current moment is shown by:

h(t)=(1−z(t))⊙h(t−1)+z(t)⊙h̅(t).

Preferentially, the output layer of the gated recurrent unit obtains the pulse energy E(t) of an excimer laser of a current moment according to the following formulas:

y(t)=σ(W_{y}·h(t))

E(t)=W_{E}·y(t)

in the formulas, y(t) represents an energy factor of the pulse energy of the current moment, W_{y} represents a weight matrix of the hidden layer state to the output layer, and W_{E} represents an output scale conversion coefficient.

Preferentially, the training dataset is a mean value of the actual laser pulse energy in the same position under each corresponding laser burst mode at each discharge high voltage,

where at each discharge high voltage, all actual laser pulse energy under each corresponding laser burst mode is the actual laser pulse energy harvested after the energy harvesting conditions are set in the single laser pulse manner in a preset moment.

Preferentially, a loss function of the gated recurrent unit network is as follows:

$$l = {\sum }_{t = 1}^{n} \frac{1}{2} {( {E}_{t} ( t ) - E ( t ) )}^{2}$$

in the formula, Eₜ(t) represents a mean value of the actual laser pulse energy in the same position under the laser burst mode at the discharge high voltage of a training sample at a current moment, E(t) represents a pulse energy sequence of the excimer laser output by the gated recurrent unit network, and n represents a specific moment.

Preferentially, the training the built gated recurrent unit network by using the training dataset includes the following steps:

Step S31: randomly selecting one training sample from the training dataset, inputting the energy harvesting conditions corresponding to the mean value of all actual laser pulse energy in the training sample into the gated recurrent unit network one by one so that a pulse energy sequence under one burst mode is obtained through gated recurrent unit network training;

Step S32: calculating a loss function of the gated recurrent unit network corresponding to the currently selected training sample, and updating training parameters of the gated recurrent unit network according to the loss function;

Step S33: calculating an error between the pulse energy sequence under the burst mode currently output by the gated recurrent unit network and the training sample; and

Step S34: circularly executing Steps S31 to S33, and ending the training to obtain the excimer laser energy model till reaching the training ending condition.

Preferentially, the training ending condition of the gated recurrent unit network is the number of preset training times, or the number of preset times of circularly executing Steps S31 to S33, and the maximum error between each pulse energy in the pulse energy sequence under the burst mode output by the gated recurrent unit network in each time and the pulse energy in the same position in the training sample is smaller than 0.15 mJ.

According to a second aspect of the embodiment of the present invention, an excimer laser energy model identification apparatus is provided, and includes a processor and a memory. The processor reads a computer program or instruction in the memory, and is configured to execute the following operations:

building a gated recurrent unit network for excimer laser energy model identification, and determining its input variable;

setting energy harvesting conditions in a single laser pulse manner in a plurality of preset moments to harvest a training dataset for excimer laser energy model identification; and

training the built gated recurrent unit network by using the training dataset, and ending the training to obtain an excimer laser energy model when reaching a training ending condition.

The excimer laser energy model identification method and apparatus provided by the present invention can precisely identify the excimer laser energy model through the gated recurrent unit network. Through verification on the excimer laser energy model, it can be known that the maximum error between the pulse energy generated by the identified excimer laser energy model and the actual pulse energy is smaller than 1.5%, and the simulation requirement of the laser energy characteristic control can be met. By using the identified excimer laser energy model, simulation study and analysis can be conveniently performed on the excimer laser energy control method, and the experiment time is shortened, so that great significance is achieved on improving the energy stability control and dose precision control of the excimer laser.

### BRIEF DESCRIPTION OF THE DRAWINGS

FIG. 1 is a flow chart of an excimer laser energy model identification method provided by an embodiment of the present invention.

FIG. 2 is a network structure diagram of a hidden layer of a gated recurrent unit network in an excimer laser energy model identification method provided by an embodiment of the present invention.

FIG. 3 is a change rule diagram of single pulse energy of an excimer laser under a constant discharge high voltage working mode.

FIG. 4 is a maximum error between the actual pulse energy and the pulse energy obtained by an excimer laser energy model at each discharge voltage in an excimer laser energy model identification method provided by an embodiment of the present invention.

FIG. 5 is a curve diagram of maximum pulse energy error change in a gated recurrent unit network training process in an excimer laser energy model identification method provided by an embodiment of the present invention.

FIG. 6a to FIG. 6c are comparison diagrams between actual single pulse energy and single pulse energy generated by an excimer laser energy model at a discharging voltage of 1550 V in an excimer laser energy model identification method provided by an embodiment of the present invention.

FIG. 7a and FIG. 7b are comparison diagrams between actual pulse energy of a 1 KHz to 4 KHz repeated-frequency laser and pulse energy generated by the model under a work condition of constant discharging high voltage of 1500 V in an excimer laser energy model identification method provided by an embodiment of the present invention.

FIG. 8 is a maximum error between actual pulse energy of a 1 KHz to 4 KHz repeated-frequency laser and pulse energy generated by the model under a work condition of constant discharging high voltage of 1500 V in an excimer laser energy model identification method provided by an embodiment of the present invention.

FIG. 9 is a schematic structural diagram of an excimer laser energy model identification apparatus provided by an embodiment of the present invention.

### DETAILED DESCRIPTION

The technical contents of the present invention will be further illustrated in detail in conjunction with drawings and specific embodiments hereafter.

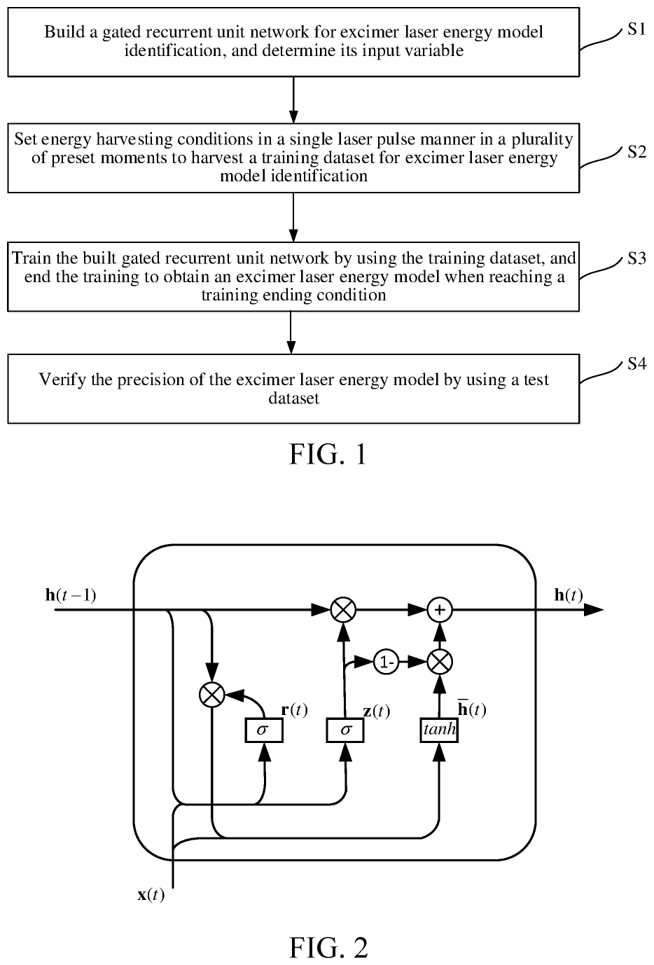

In order to solve the problem of great differences between an actual excimer laser output beam energy sequence and a pulse energy sequence generated by an existing excimer laser energy model, as shown in FIG. 1, an embodiment of the present invention firstly provides an excimer laser energy model identification method, mainly including the following steps:

Step S1: a gated recurrent unit network for excimer laser energy model identification is built.

In the embodiment of the present invention, an excimer laser energy model is obtained by using gated recurrent unit network identification. The gated recurrent unit network includes gated recurrent units corresponding to a plurality of time sequences, each of the gated recurrent units includes an input layer, a hidden layer and an output layer, the input layer is connected with the hidden layer, the hidden layer is connected with the output layer, and the hidden layers of the adjacent gated recurrent units are connected.

The input layer of the gated recurrent unit corresponding to the current time sequence receives an input variable of the current moment, and inputs the input variable into the hidden layer of the gated recurrent unit, the hidden layer obtains the state of the hidden layer at the current moment according to the received state of the hidden layer at the former moment and the input variable, the state of the hidden layer is input to the output layer of the gated recurrent unit in one aspect to obtain the pulse energy of the excimer laser at the current moment, and is input into the hidden layer of the gated recurrent unit corresponding to the next time sequence to be used as its input in the other aspect. Each moment corresponds to one time sequence.

Specifically, by analyzing the output beam energy characteristics of the excimer laser, it can be known that the condition variables directly influencing the output beam energy of the excimer laser are the time interval of single laser pulses and a discharge high voltage value, and the time interval of the single laser pulses refers to the time interval from a current laser pulse to a former laser pulse. Therefore, the input variables of the gated recurrent unit network are selected to be the time interval of single laser pulses and the discharge high voltage value, as shown by Formula (1).

$$x ( t ) = {W}_{in} [ \begin{matrix}HV ( t ) \\ Δ t ( t )\end{matrix} ] \qquad ( 1 )$$

In the formula, x(t) represents an input variable of the gated recurrent unit network at a moment t, HV (t) represents a discharge high voltage value of the laser pulse of the excimer laser at the moment t, Δt(t) represents the time interval of the laser pulse of the excimer laser at the moment t, and Wᵢₙ represents an input scale conversion matrix.

As shown in FIG. 2, the hidden layer of each of the gated recurrent units includes a reset gate r(t), a refresh gate z(t) and a candidate hidden layer state h̅(t), and the hidden layer uses the hidden layer state h(t−1) of a former moment and an input variable x(t) of a current moment as inputs, and processes the hidden layer state of the former moment to obtain the hidden layer state h(t) of the current moment when using the hidden layer state of the former moment.

The refresh gate z(t) represents the information amount brought by the state of a former moment to a current moment, is used for capturing a long-term dependency relationship in the time sequence, and has an expression as shown by Formula (2).

z(t)=σ(W_{z}·x(t)+U_{z}·h(t−1)) (2)

in the formula, σ represents an activation function, the activation function is a sigmoid function, W_{z} represents an input weight matrix of the refresh gate, x(t) represents an input variable of the gated recurrent unit network at the current moment, U_{z} represents a transfer matrix of the hidden layer state of the refresh gate, and h(t−1) represents a hidden layer state of a former moment.

The reset gate r(t) represents a degree of the current state ignoring the former moment state, and is used for capturing a short-term dependency relationship in the time sequence. The reset gate r(t) selects a sigmoid function, expressed as σ, as an activation function, and has an expression as shown by Formula (3).

r(t)=Σ(Wᵣ·x(t)+Uᵣ·h(t−1)) (3)

In the formula, Wᵣ represents an input weight matrix of a reset gate, x(t) represents an input variable of the gated recurrent unit network at a current moment, Uᵣ represents a transfer matrix of the hidden layer state of the reset gate, and h(t−1) represents a hidden layer state of a former moment.

The candidate hidden layer state h̅(t) is used for assisting the calculation of the hidden layer state h(t), selects a tanh function as an activation function, and has an expression as shown by Formula (4).

h̅(t)=tan h(W·x(t)+U·(r(t)⊙h(t−1))) (4)

In the formula, W represents an input weight matrix of the candidate hidden layer state, x(t) represents an input variable of the gated recurrent unit network at a current moment, U represents a transfer matrix of the candidate hidden layer state aiming at the hidden layer state of a former moment, ⊙ represents a Hadamard product, and h(t−1) represents a hidden layer state of a former moment.

An expression of the hidden layer state h(t) of the current moment is shown by Formula (5).

h(t)=(1−z(t))⊙h(t−1)+z(t)⊙h̅(t) (5)

In the formula, z(t) represents a refresh gate, h(t−1) represents a hidden layer state of a former moment, h̅(t) represents a candidate hidden layer state h̅(t), and ⊙ epresents a Hadamard product.

The output layer of the gated recurrent unit is used for obtaining the pulse energy E(t) of an excimer laser of a current moment according to the hidden layer state h(t) of the current moment, and the pulse energy is obtained according to Formulas (6) and (7). Specifically, an energy factor y(t) of the pulse energy of the current moment is obtained according to Formula (6), and the energy factor y(t) selects a sigmoid function as an activation function, expressed as σ.

y(t)=σ(W_{y}·h(t)) (6)

In the formula, W_{y} represents a weight matrix of the hidden layer state to the output layer, and h(t) represents a hidden layer state of a current moment.

The pulse energy sequence E(t) of the excimer laser at the current moment is obtained according to the energy factor y(t) of the pulse energy of the current moment and Formula (7).

E(t)=W_{E}·y(t) (7)

In the formula, W_{E} represents an output scale conversion coefficient, and y(t) represents an energy factor of the pulse energy of a current moment.

From a comprehensive view of Formulas (1) to (7), the embodiment of the present invention builds a gated recurrent unit network for excimer laser energy model identification.

Step S2: energy harvesting conditions are set in a single laser pulse manner in a plurality of preset moments to harvest a test dataset and a training dataset for excimer laser energy model identification.

The energy harvesting conditions of the single pulses refer to the time interval of single laser pulses and a discharge high voltage value, i.e., the time interval from the current laser pulse to the former laser pulse and the discharge high voltage corresponding to the current laser pulse.

The training dataset for excimer laser energy model identification is a mean value of the actual laser pulse energy in the same position under each corresponding laser burst mode at each discharge high voltage. That is, one discharge high voltage corresponds to one mean value of the actual laser pulse energy in the same position under each laser burst mode. At each discharge high voltage, all actual laser pulse energy under each corresponding laser burst mode is the actual laser pulse energy harvested after the energy harvesting conditions are set in a single laser pulse manner in a preset moment.

At each discharge high voltage in the training dataset, the mean values of the actual laser pulse energy in the same position under each corresponding laser burst mode form a mean value sequence of the actual laser pulse energy under one burst mode, and it is used as a training sample in the training dataset.

The test dataset for excimer laser energy model identification is a mean value of the actual laser pulse energy in the same position under each corresponding laser burst mode at the at least one discharge high voltage. At each discharge high voltage, a harvesting method of all actual laser pulse energy under each corresponding laser burst mode is the same as a training dataset harvesting method. At each discharge high voltage in the test dataset, the mean values of the actual laser pulse energy in the same position under each corresponding laser burst mode form a mean value sequence of the actual laser pulse energy under one burst mode, and it is used as a test sample in the test dataset.

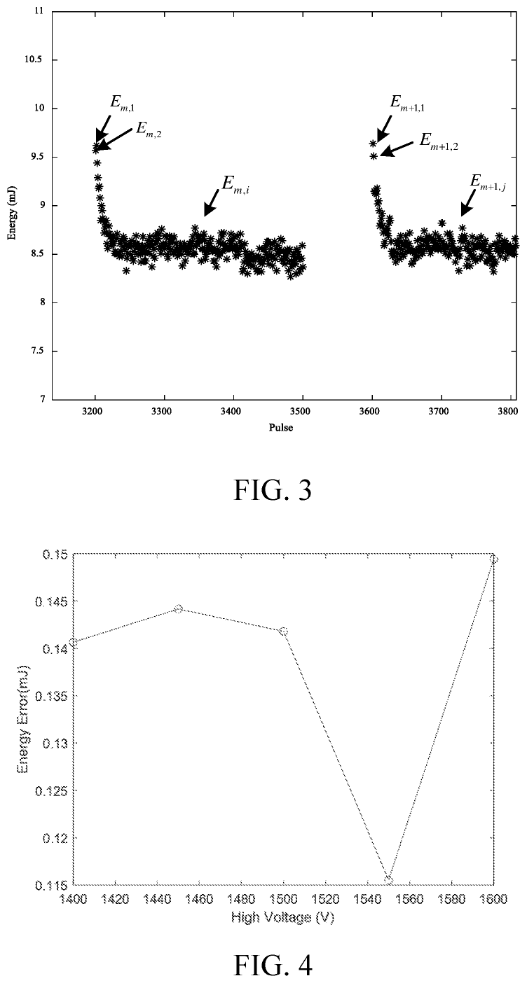

Specifically, in semiconductor photoetching application, the excimer laser works under the burst mode, so that each moment may correspond to one time sequence, and each time sequence may correspond to one burst mode. Under the burst mode, the harvested pulse energy sequence of the excimer laser is shown in FIG. 3. From the figure, it can be seen that in the sequence of the harvested pulse energy under each burst mode, there may be overshoot to different scales in the several former pulse energy (such as E_{m,1}, E_{m,2}, E_{m+1,1} and E_{m+1,2} in FIG. 3), and at the same time, there will also be energy fluctuation (such as E_{m,i} and E_{m+1,j} in FIG. 3) in a later stable region under the burst mode. Under the condition of constant discharge high voltage, the pulse energy of the excimer laser has a great relationship with its position in the harvested pulse energy sequence under the burst mode. Therefore, during the analysis on the excimer laser energy characteristics, the pulse energy in different positions in the harvested pulse energy sequence under the burst mode is separately analyzed.

In order to remove the noise in the pulse energy in the harvested laser pulse energy sequence under the burst mode, Formula (8) is adopted to obtain a mean value of the pulse energy in different positions in each harvested laser pulse energy sequence under the burst mode.

$${\overline{E}}_{i} = \frac{{\sum }_{m = 1}^{N} {E}_{m , i}}{N} \qquad ( 8 )$$

In the formula, Ē represents a mean value of an i^{th} laser pulse energy in the harvested laser pulse energy sequence under each burst mode, E_{m,i} represents an i^{th} laser pulse energy in the harvested laser pulse energy sequence under the m^{th} burst mode, and N represents the quantity of the harvested laser pulse energy sequences under the burst modes at the preset moment.

By taking a KrF excimer laser generating a wavelength of 248 nm during the harvesting of the training dataset for excimer laser energy model identification as an example, the wavelength of the excimer laser may influence the harvested actual pulse energy data, so in an experimental process, a wavelength is controlled at 248.327 nm by using a feedback technology, the excimer laser works at a repeated frequency of 1 KHz, the time interval and the discharge high voltage value are set for the laser pulses one by one, the pulse laser energy of the laser respectively at the discharge high voltages of 1400 V, 1450 V, 1550 V and 1600 V are respectively harvested for 1 min by using an energy detector, the energy detector harvests the actual pulse energy sequences of the excimer laser under 100 burst modes at each discharge high voltage within one minute, and the actual pulse energy sequence under each burst mode includes 250 pulse energy. In each actual pulse energy sequence under the burst mode, the time interval between pulses corresponding to each pulse energy is a reciprocal of the repeated frequency, and the unit may be ms. For the actual pulse energy sequences under the 100 burst modes at each discharge high voltage, according to Formula (8), from the first pulse energy in the actual pulse energy sequence under each burst mode, the mean values of the actual laser pulse energy in the same position under the laser burst mode at each discharge high voltage are respectively calculated to obtain a mean value sequence of the actual pulse energy under one burst mode corresponding to each discharge high voltage. By taking the calculation of the mean value of the actual laser pulse energy in the first position under the laser burst mode at any one discharge high voltage as an example, it may be obtained by adding the first actual pulse energy in the pulse energy sequences under 100 burst modes and dividing the sum by 100.

Therefore, the mean value sequences of the actual pulse energy under the burst modes corresponding to the discharge high voltages of 1400 V, 1450 V, 1550 V and 1600 V form a training dataset for excimer laser energy model identification. That is, there are mean value sequences of actual pulse energy under 4 burst modes, and each discharge high voltage corresponds to the mean value sequence of the actual pulse energy under one burst mode.

By taking a KrF excimer laser generating a wavelength of 248 nm during the use for the test dataset for excimer laser energy model identification as an example, the excimer laser works at a repeated frequency of 1 KHz, the time interval and the discharge high voltage value are set for the laser pulses one by one, the pulse laser energy of the laser at a discharge high voltage of 1550 V is harvested by using an energy detector for 1 min, the mean value of the actual laser pulse energy of the laser in the same position under the burst mode at this discharge high voltage is calculated by using the same method as the training dataset, and the mean value sequence of the pulse energy under one burst mode corresponding to the discharge high voltage is obtained. It needs to be noted that according to actual requirements, for the test dataset for excimer laser energy model identification, at the single constant working repeated frequency or different working repeated frequencies, the time interval and the discharge high voltage value are set for each laser pulse one by one, the mean value sequences of a plurality of pretreated actual pulse energy under the burst modes corresponding to discharge high voltages at the preset moment are collected, and for example, mean values of the actual pulse energy of the laser in the same position under the burst mode at the 1500 V discharge high voltage obtained when the excimer laser working repeated frequencies are respectively 1 KHz, 2 KHz, 3 KHz and 4 KHz may be obtained by using a method the same as that of obtaining the training dataset.

Step S3: the built gated recurrent unit network is trained by using the training dataset, and the training is ended to obtain an excimer laser energy model when reaching a training ending condition.

Each weight matrix in the built gated recurrent unit network for excimer laser energy model identification needs to be obtained through study, so that the gated recurrent unit network needs to be trained. In practical application, a used training method is a BPTT (Backpropagation Through Time) method.

When the gated recurrent unit network is applied to excimer laser energy model identification, one burst mode is used as one time sequence, and a loss function defining the whole network is shown by Formula (9).

$$l = {\sum }_{t = 1}^{n} \frac{1}{2} {( {E}_{t} ( t ) - E ( t ) )}^{2} \qquad ( 9 )$$

in the formula, Eₜ(t) represents a mean value of the actual laser pulse energy in the same position under the laser burst mode at the discharge high voltage of a training sample at a current moment, E(t) represents a pulse energy sequence of the excimer laser output by the gated recurrent unit network, and n represents a specific moment.

If the input of the activation function is set to be net_{y}(t)=W_{y}·h(t),

$$\frac{\partial l}{\partial {net}_{y} ( t )} = \frac{\partial l}{\partial E ( t )} \cdot \frac{\partial E ( t )}{\partial y ( t )} \cdot \frac{\partial y ( t )}{\partial {net}_{y} ( t )} = ( {E}_{t} ( t ) - E ( t ) ) \cdot {W}_{E} \cdot {σ}^{′} ( {net}_{y} ( t ) ) . \qquad ( 10 )$$

Then, the following can be obtained:

$$\frac{\partial l}{\partial {W}_{y}} = {\sum }_{t = 1}^{n} ( \frac{\partial l}{\partial {net}_{y} ( t )} \cdot {( \frac{\partial {net}_{y} ( t )}{\partial h ( t )} )}^{T} ) = {\sum }_{t = 1}^{n} ( ( {E}_{t} ( t ) - E ( t ) ) \cdot {W}_{E} \cdot {σ}^{′} ( {net}_{y} ( t ) ) \cdot {h}^{T} ( t ) ) . \qquad ( 11 )$$

In the formula, σ′ (net_{y}(t)) represents a derivative of σ (net_{y}(t)).

In a case that t=n,

$$\frac{\partial l}{\partial h ( t )} = {( \frac{\partial {net}_{y} ( t )}{\partial h ( t )} )}^{T} \cdot \frac{\partial l}{\partial {net}_{y} ( t )} = {W}_{y}^{T} \cdot ( {E}_{t} ( t ) - E ( t ) ) \cdot {W}_{E} \cdot {σ}^{′} ( {net}_{y} ( t ) ) . \qquad ( 12 )$$

In a case that t<n,

$$\frac{\partial l}{\partial h ( t )} = {( \frac{\partial {net}_{y} ( t )}{\partial h ( t )} )}^{T} \cdot \frac{\partial l}{\partial {net}_{y} ( t )} + {( \frac{\partial z ( t + 1 )}{\partial h ( t )} )}^{T} \cdot \frac{\partial l}{\partial z ( t + 1 )} + {( \frac{\partial r ( t + 1 )}{\partial h ( t )} )}^{T} \cdot \frac{\partial l}{\partial r ( t + 1 )} + {( \frac{\partial \overline{h}}{( t + 1 ) \partial h ( t )} )}^{T} \cdot \frac{\partial l}{\partial \overline{h} ( t + 1 )} + {( \frac{\partial h ( t + 1 )}{\partial h ( t )} )}^{T} \cdot \frac{\partial l}{\partial h ( t + 1 )} . \qquad ( 13 )$$

where

$$\frac{\partial l}{\partial h ( t + 1 )} = \frac{\partial l}{\partial h ( t + 1 )} ⊙ \frac{\partial h ( t + 1 )}{\partial h ( t + 1 )} ⊙ ( \overline{h} ( t + 1 ) - h ( t ) ) \qquad ( 14 )$$

$$\frac{\partial l}{\partial \overline{h} ( t + 1 )} = \frac{\partial l}{\partial h ( t + 1 )} ⊙ \frac{\partial h ( t + 1 )}{\partial \overline{h} ( t + 1 )} = \frac{\partial l}{\partial h ( t + 1 )} ⊙ z ( t + 1 ) \qquad ( 15 )$$

$$\frac{\partial l}{\partial r ( t + 1 )} = {( \frac{\partial \overline{h} ( t + 1 )}{\partial r ( t + 1 )} )}^{T} \cdot \frac{\partial l}{\partial \overline{h} ( t + 1 )} = diag ( {tanh}^{′} ( {net}_{\overline{h} i} ( t + 1 ) ) ) \cdot {U}^{T} ⊙ h ( t ) \cdot \frac{\partial l}{\partial h ( t + 1 )} \qquad ( 16 )$$

Through Formulas (12) to (16), when

$$t < n , \frac{\partial l}{\partial h ( t )}$$

is a recursive expression relevant to

$$\frac{\partial l}{\partial h ( t + 1 )} ,$$

so during the training of the gated recurrent unit network,

$$\frac{\partial l}{\partial h ( t )}$$

is reversely calculated from t=n, and at the same time,

$$\frac{\partial l}{\partial z ( t )} , \frac{\partial l}{\partial \overline{h} ( t )} and \frac{\partial l}{\partial r ( t )}$$

may be calculated.

If the input of the activation function is set to be net_{z}(t)=W_{z}·x(t)+U_{z}·h(t−1), by aiming at the gradient of W_{z}, there is

$$\frac{\partial l}{\partial {W}_{z}} = {\sum }_{t = 0}^{n} ( {( \frac{\partial z ( t )}{\partial {W}_{z}} )}^{T} \cdot \frac{\partial l}{\partial z ( t )} ) = {\sum }_{t = 0}^{n} ( diag ( {σ}^{′} ( {net}_{zi} ( t ) ) ) \cdot \frac{\partial l}{\partial z ( t )} \cdot {x}^{T} ( t ) ) . \qquad ( 17 )$$

By aiming at the gradient of U_{z}, there is

$$\frac{\partial l}{\partial {U}_{z}} = {\sum }_{t = 0}^{n} ( {( \frac{\partial z ( t )}{\partial {U}_{z}} )}^{T} \cdot \frac{\partial l}{\partial z ( t )} ) = {\sum }_{t = 0}^{n} ( diag ( {σ}^{′} ( {net}_{zi} ( t ) ) ) \cdot \frac{\partial l}{\partial z ( t )} \cdot {h}^{T} ( t - 1 ) ) . \qquad ( 18 )$$

In the formula, diag(●) represents a diagonal matrix, and net_{zi}(t) represents an i^{th} component of net_{z}(t).

If the input of the activation function is set to be netₕ(t)=W·x(t)+U·(r(t)⊙h(t−1)), by aiming at the gradient of W, there is

$$\frac{\partial l}{\partial W} = {\sum }_{t = 0}^{n} ( {( \frac{\partial \overline{h} ( t )}{\partial W} )}^{T} \cdot \frac{\partial l}{\partial \overline{h} ( t )} ) = {\sum }_{t = 0}^{n} ( diag ( {tanh}^{′} ( {net}_{\overline{h} i} ( t ) ) ) \cdot \frac{\partial l}{\partial \overline{h} ( t )} \cdot {x}^{T} ( t ) ) . \qquad ( 19 )$$

By aiming at the gradient of U, there is

$$\frac{\partial l}{\partial U} = {\sum }_{t = 0}^{n} ( {( \frac{\partial \overline{h} ( t )}{\partial U} )}^{T} \cdot \frac{\partial l}{\partial \overline{h} ( t )} ) = {\sum }_{t = 0}^{n} ( diag ( {tanh}^{′} ( {net}_{\overline{h} i} ( t ) ) ) \cdot \frac{\partial l}{\partial \overline{h} ( t )} \cdot {( r ( t ) ⊙ h ( t - 1 ) )}^{T} ) . \qquad ( 20 )$$

In the formula, tanh′(●) represents a derivative of tanh(●), and net_{h̅i}(t) represents an i^{th} component of net_{h̅}(t).

If the input of the activation function is set to be netᵣ(t)=Wᵣ·x(t)+Uᵣ·h(t−— 1), by aiming at the gradient of Wᵣ, there is

$$\frac{\partial l}{\partial {W}_{r}} = {\sum }_{t = 0}^{n} ( {( \frac{\partial r ( t )}{\partial {W}_{r}} )}^{T} \cdot \frac{\partial l}{\partial r ( t )} ) = {\sum }_{t = 0}^{n} ( diag ( {σ}^{′} ( {net}_{ri} ( t ) ) ) \cdot \frac{\partial l}{\partial r ( t )} \cdot {x}^{T} ( t ) ) . \qquad ( 21 )$$

By aiming at the gradient of Uᵣ, there is

$$\frac{\partial l}{\partial {U}_{r}} = {\sum }_{t = 0}^{n} ( {( \frac{\partial r ( t )}{\partial {U}_{r}} )}^{T} \cdot \frac{\partial l}{\partial r ( t )} ) = {\sum }_{t = 0}^{n} ( diag ( {σ}^{′} ( {net}_{ri} ( t ) ) ) \cdot \frac{\partial l}{\partial r ( t )} \cdot {h}^{T} ( t - 1 ) ) . \qquad ( 22 )$$

In the formula, netᵣᵢ(t) represents an i^{th} component of netᵣ(t).

From Formulas (9) to (22), an updating method of a training parameter of the gated recurrent unit network may be obtained, as shown by Formulas (23) to (29).

$$\begin{matrix}{W}_{y} ( i + 1 ) = {W}_{y} ( i ) - λ \cdot \frac{\partial l}{\partial {W}_{y}} & ( 23 ) \\ {W}_{z} ( i + 1 ) = {W}_{z} ( i ) - λ \cdot \frac{\partial l}{\partial {W}_{z}} & ( 24 ) \\ {U}_{z} ( i + 1 ) = {U}_{z} ( i ) - λ \cdot \frac{\partial l}{\partial {U}_{z}} & ( 25 ) \\ W ( i + 1 ) = W ( i ) - λ \cdot \frac{\partial l}{\partial W} & ( 26 ) \\ U ( i + 1 ) = U ( i ) - λ \cdot \frac{\partial l}{\partial U} & ( 27 ) \\ {W}_{r} ( i + 1 ) = {W}_{r} ( i ) - λ \cdot \frac{\partial l}{\partial {W}_{r}} & ( 28 ) \\ {U}_{r} ( i + 1 ) = {U}_{r} ( i ) - λ \cdot \frac{\partial l}{\partial {U}_{r}} & ( 29 )\end{matrix}$$

In the formula, W_{y}(i+1) represents a weight matrix of the current hidden layer state to the output layer, W_{y}(i) represents a weight matrix of the former hidden layer state to the output layer, W_{z}(i+1) represents a current input weight matrix of the refresh gate, W(i) represents a former input weight matrix of the refresh gate, U_{z}(i+1) represents a transfer matrix of the current hidden layer state of the refresh gate, U_{z}(i) represents a transfer matrix of the former hidden layer state of the refresh gate, W(i+1) represents an input weight matrix of the current candidate hidden layer state, W(i) represents an input weight matrix of the former candidate hidden layer state, U(i+1) represents a transfer matrix of the current candidate hidden layer state aiming at the hidden layer state of a former moment, U(i) represents a transfer matrix of the former candidate hidden layer state aiming at the hidden layer state of a former moment, Wᵣ(i+1) represents a current input weight matrix of the reset gate, Wᵣ(i) represents a former input weight matrix of the reset gate, Uᵣ(i+1) represents a transfer matrix of the current hidden layer state of the reset gate, Uᵣ(i) represents a transfer matrix of the former hidden layer state of the reset gate, and λ represents a study step length.

The operation of training the built gated recurrent unit network by using the training dataset includes the following steps:

Step S31: one training sample is randomly selected from the training dataset, the energy harvesting conditions corresponding to the mean value of all actual laser pulse energy in the training sample are input into the gated recurrent unit network one by one so that a pulse energy sequence under a burst mode is obtained through gated recurrent unit network training.

In order to sufficiently utilize data, during training of the gated recurrent unit network in each time, one training sample is randomly selected from the training dataset, for example, a mean value sequence of the actual pulse energy under the burst mode at the 1600 V discharge high voltage from a training dataset for excimer laser energy model identification (actual pulse energy sequences under 4 burst modes) formed by the mean value sequence of the actual pulse energy under the burst mode corresponding to the discharge high voltages of 1400 V, 1450 V, 1550 V and 1600 V, the energy harvesting conditions (time interval and discharge high voltage values of single laser pulses) corresponding to the mean value of each actual pulse energy in the mean value sequence of the actual pulse energy under the burst mode are input into the gated recurrent unit network one by one, and after the training by the gated recurrent unit network, a pulse energy sequence under one burst mode is output.

Step S32: a loss function of the gated recurrent unit network corresponding to the currently selected training sample is calculated, and training parameters of the gated recurrent unit network are updated according to the loss function.

The mean value sequence of the selected actual pulse energy under the burst mode corresponding to the 1600 V discharge high voltage and the pulse energy sequence under the burst mode corresponding to the 1600 V discharge high voltage output after the training of the gated recurrent unit network are put into Formula (9), a loss function of the gated recurrent unit network is calculated, and training parameters of the gated recurrent unit network may be updated according to the loss function in combination with Formulas (23) to (29).

Step S33: an error between the pulse energy sequence under the burst mode currently output by the gated recurrent unit network and the training sample is calculated.

Subtraction is performed between each pulse energy in the pulse energy sequence under the burst mode at the 1600 V discharge high voltage currently output by the gated recurrent unit network and the pulse energy in the same position in the training sample (the mean value sequence of the actual pulse energy under the burst mode at the 1600 V discharge high voltage) to obtain an error between each pulse energy in the pulse energy sequence under the burst mode currently output by the gated recurrent unit network and the pulse energy in the same position of the training sample.

Step S34: Steps S31 to S33 are circularly executed, and the training is ended to obtain the excimer laser energy model till reaching the training ending condition.

The training ending condition of the gated recurrent unit network may be the number of preset training times (such as one hundred thousand times), or the number of preset times of circularly executing Steps S31 to S33, and the maximum error between each pulse energy in the pulse energy sequence under the burst mode output by the gated recurrent unit network at each discharge high voltage in each time and the pulse energy in the same position in the training sample is smaller than 0.15 mJ (as shown in FIG. 4, the pulse energy errors under the burst mode at each discharge high voltage are all smaller than 0.15 mJ. Since the energy center value is 10 mJ, so that the relative error is smaller than 1.5%).

By training the gated recurrent unit network, final training parameters W_{y}, W_{z}, U_{z}, W, U, Wᵣ and Uᵣ of the excimer laser energy model can be obtained, and the excimer laser energy model is generated according to Formulas (1) to (7).

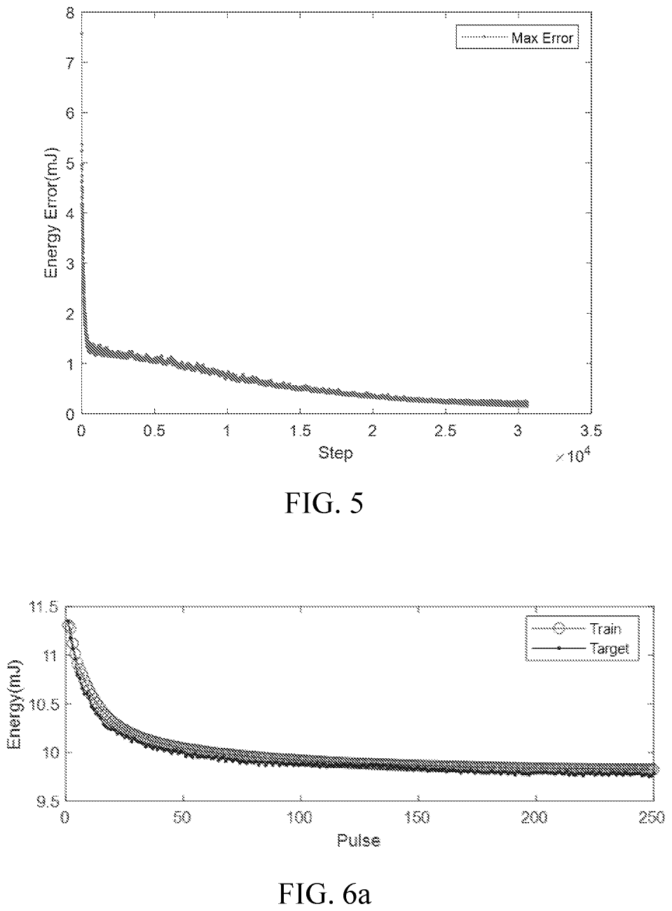

It needs to be noted that in the training process of the gated recurrent unit network, the maximum pulse energy error change output by the gated recurrent unit network under the burst mode at a certain discharge high voltage is shown in FIG. 5, the step length of the horizontal axis is the number of training times of the gated recurrent unit network, the vertical coordinate is an absolute value of the pulse energy error output by the gated recurrent unit network. From FIG. 5, it can be seen that the maximum error of the pulse energy output by the gated recurrent unit network is gradually reduced until it is smaller than 0.15 mJ. This result proves that the gated recurrent unit network for excimer laser energy model identification built by the present invention is convergent in the training process.

Step S4: the precision of the excimer laser energy model is verified by using a test dataset.

The precision of the excimer laser energy model is verified by using the mean value sequence of a plurality of pretreated actual pulse energy under the burst mode corresponding to the discharge high voltages harvested at a single constant working repeated frequency or different working repeated frequencies.

For example, the excimer laser energy model is verified by selecting the mean value sequence of the actual pulse energy under the burst mode at the 1550 V discharge high voltage. The energy harvesting conditions (time interval and discharge high voltage values of single laser pulses) corresponding to the mean value of each actual pulse energy in the mean value sequence of the actual pulse energy under the burst mode are input into the gated recurrent unit network one by one, and the excimer laser energy model may output a pulse energy sequence under one burst mode.

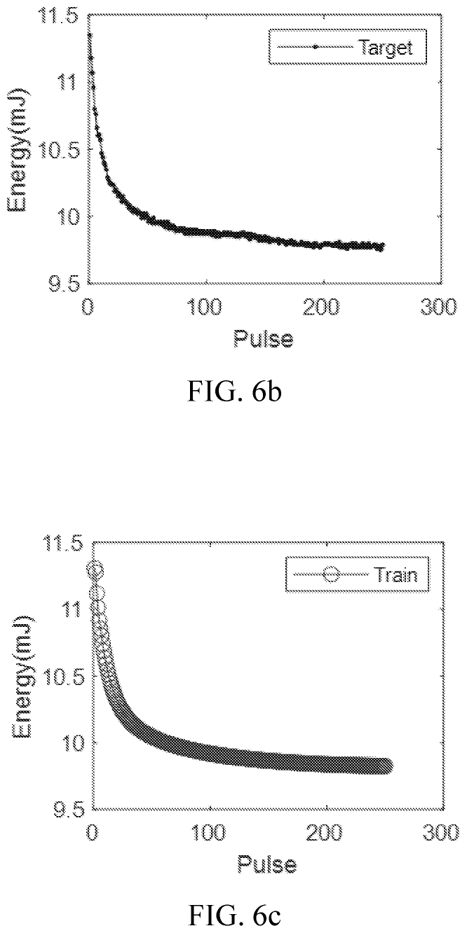

Subtraction is performed between each pulse energy in the pulse energy sequence under the burst mode at the 1550 V discharge high voltage output by the excimer laser energy model and the pulse energy in the same position in the mean value sequence of the actual pulse energy under the burst mode at the 1550 V discharge high voltage to obtain an error between the actual pulse energy and each pulse energy in the pulse energy sequence under the burst mode output by the excimer laser energy model. As shown in FIG. 6a to FIG. 6c, FIG. 6b shows the actual pulse energy change under the burst mode at the 1550 V discharge high voltage, FIG. 6c shows the pulse energy change under the burst mode at the 1550 V discharge high voltage output by the excimer laser energy model, and FIG. 6a shows a contact ratio between the actual pulse energy change and the pulse energy change under the burst mode at the 1550 V discharge high voltage output by the excimer laser energy model. From the figure, it can be seen that there is a good contact ratio between the pulse energy change obtained through the excimer laser energy model and the actual pulse energy change.

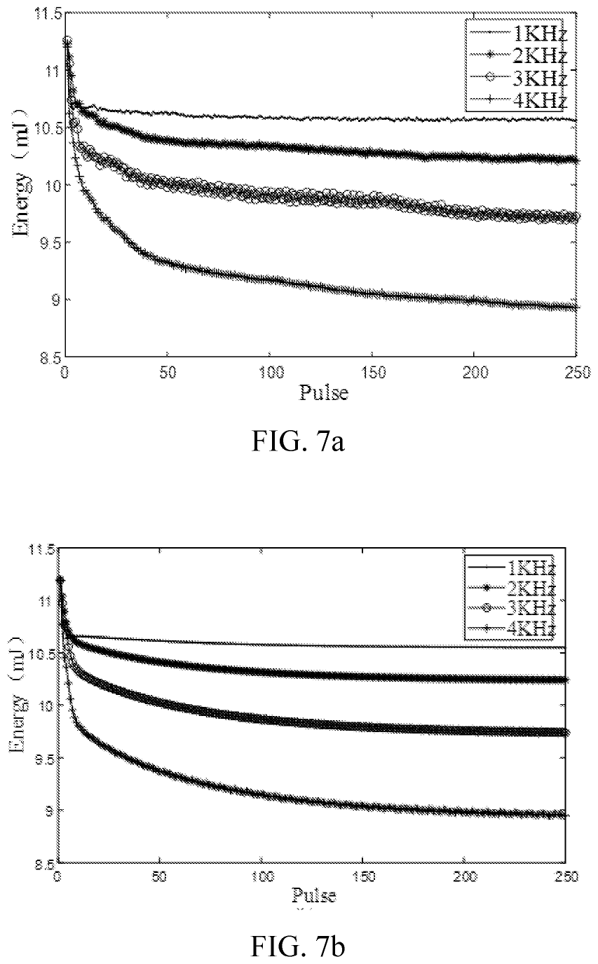

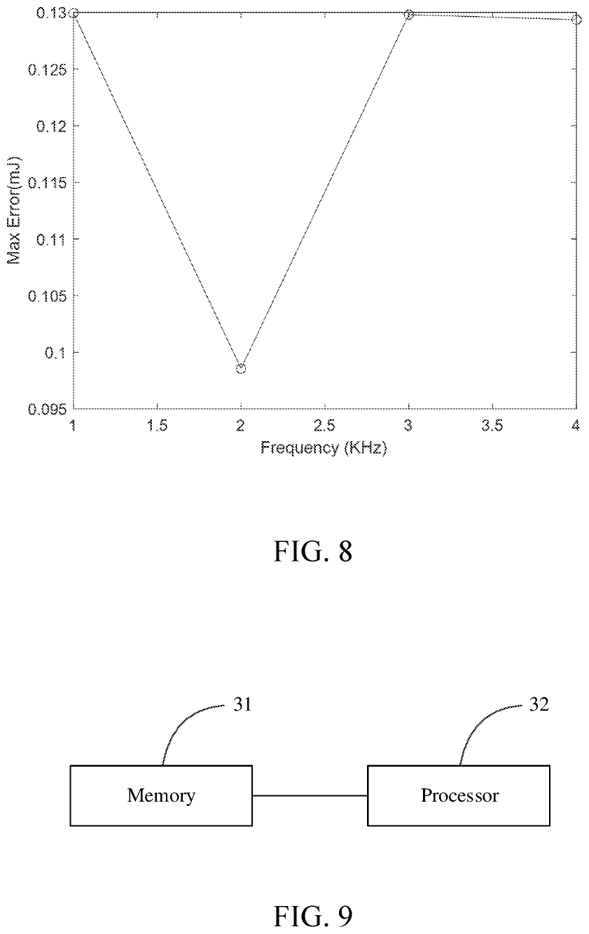

For another example, the excimer laser energy model is verified by respectively selecting the mean value sequence of the 1 KHz to 4 KHz actual pulse energy under the burst mode at the 1500 V discharge high voltage, as shown in FIG. 7a to FIG. 7b, FIG. 7a shows the 1 KHz to 4 KHz actual pulse energy change under the burst mode at the 1500 V discharge high voltage, and FIG. 7b shows the 1 KHz to 4 KHz pulse energy change under the burst mode at the 1500 V discharge high voltage output by the excimer laser energy model. By comparing FIG. 7a and FIG. 7b, it is not difficult to discover that for the pulse energy obtained by the excimer laser energy model at different repeated frequencies, the laser energy change under the burst mode is consistent with the actually measured laser energy, and its maximum error is shown in FIG. 8. From the figure, it can be seen that the maximum error at different repeated frequencies is smaller than 0.13 mJ, that is, the maximum error is smaller than 1.5%.

It can be seen through the relationship between the dose precision and energy stability that when the dose precision of 0.5% for photoetching is met, the maximum error of the energy stability is 2.74%. The error of the pulse energy generated by the excimer laser energy model provided by the invention is smaller than the error of the energy stability control precision, so that the model meets the simulation requirements of the laser energy characteristic control.

Additionally, as shown in FIG. 9, the embodiment of the present invention further provides an excimer laser energy model identification apparatus which includes a processor 32 and a memory 31, and may further include a communication assembly, a sensor assembly, a power supply assembly, a multimedia assembly and an input/output interface according to practical requirements. The memory, the communication assembly, the sensor assembly, the power supply assembly, the multimedia assembly and the input/output interface are all connected with the processor 32. As mentioned above, the memory 31 may be a SRAM (Static Random Access Memory), an EEPROM (Electrically Erasable Programmable Read-Only Memory), an EPROM (Erasable Programmable Read-Only Memory), a PROM (Programmable Read-Only Memory), a ROM (Read-Only Memory), a magnetic memory, a flash memory, etc. The processor 32 may be a CPU (Central Processing Unit), a GPU (Graphics Processing Unit), an FPGA (Field-Programmable Gate Array), an ASIC (Application-Specific Integrated Circuit), a DSP (Digital Signal Processing) chip, etc. Other components such as the communication assembly, the sensor assembly, the power assembly and the multimedia assembly may be realized by general components in an existing smartphone, and they will not be specifically illustrated herein.

Additionally, an excimer laser energy model identification apparatus provided by the embodiment of the present invention includes the processor 32 and the memory 31. The processor 32 reads a computer program or instruction in the memory 31, and is configured to execute the following operations:

A gated recurrent unit network for excimer laser energy model identification is built.

Energy harvesting conditions are set in a single laser pulse manner in a plurality of preset moments to harvest a training dataset for excimer laser energy model identification.

The built gated recurrent unit network is trained by using the training dataset, and the training is ended to obtain an excimer laser energy model when reaching a training ending condition.

Additionally, the embodiment of the present invention further provides a computer readable storage medium. Instructions are stored on the readable storage medium. When the instructions run on a computer, the computer is enabled to execute the excimer laser energy model identification method as shown in FIG. 1. Its specific implementation is not repeated herein.

Additionally, the embodiment of the present invention further provides a computer program product including instructions. When the computer program product runs on a computer, the computer is enabled to execute the excimer laser energy model identification method as shown in FIG. 1. Its specific implementation is not repeated herein.

The excimer laser energy model identification method and apparatus provided by the embodiment of the present invention can precisely identify the excimer laser energy model through the gated recurrent unit network. Through verification on the excimer laser energy model, it can be known that the maximum error between the pulse energy generated by the identified excimer laser energy model and the actual pulse energy is smaller than 1.5%, and the simulation requirement of the laser energy characteristic control can be met. By using the identified excimer laser energy model, simulation study and analysis can be conveniently performed on the excimer laser energy control method, and the experiment time is shortened, so that great significance is achieved on improving the energy stability control and dose precision control of the excimer laser.

The excimer laser energy model identification method and apparatus provided by the present invention are illustrated in detail above. For those of ordinary skill in the art, any obvious change done on the premise without departing from the substantive contents of the present invention shall all fall within the protection scope of the present invention.

What is claimed is:

1. An excimer laser energy model identification method, comprising the following steps:
Step S1: building a gated recurrent unit network for excimer laser energy model identification;
Step S2: setting energy harvesting conditions in a single laser pulse manner in a plurality of preset moments to harvest a training dataset for excimer laser energy model identification; and
Step S3: training the built gated recurrent unit network by using the training dataset, and ending the training to obtain an excimer laser energy model when reaching a training ending condition.

2. The excimer laser energy model identification method according to claim 1, wherein
the gated recurrent unit network comprises gated recurrent units corresponding to a plurality of time sequences;
each of the gated recurrent units comprises an input layer, a hidden layer and an output layer; and
the input layer is connected with the hidden layer, the hidden layer is connected with the output layer, and the hidden layers of the adjacent gated recurrent units are connected.

3. The excimer laser energy model identification method according to claim 1, wherein
the energy harvesting conditions refer to the time interval of single laser pulses and a discharge high voltage value, and the time interval of the single laser pulses refers to the time interval from a current laser pulse to a former laser pulse.

4. The excimer laser energy model identification method according to claim 1, wherein
the hidden layer of each of the gated recurrent units comprises a reset gate r(t), a refresh gate z(t) and a candidate hidden layer state h̅(t);
the refresh gate z(t) represents the information amount brought by the state of a former moment to a current moment, and is shown by:
z(t)=σ(W_{z}·x(t)+U_{z}·h(t−1))
in the formula, σ represents an activation function, the activation function is a sigmoid function, W_{z} represents an input weight matrix of the refresh gate, x(t) represents an input variable of the current gated recurrent unit network, U_{z} represents a transfer matrix of the hidden layer state of the refresh gate, and h(t−1) represents a hidden layer state of a former moment;
the reset gate r(t) represents a degree of the current state ignoring the former moment state, and is shown by:
r(t)=σ(Wᵣ·x(t)+Uᵣ·h(t−1))
in the formula, Wᵣ represents an input weight matrix of the reset gate, and Uᵣ represents a transfer matrix of the hidden layer state of the reset gate;
the candidate hidden layer state h̅(t) is used for assisting the calculation of the hidden layer state h(t), and is shown by:
h̅(t)=tan h(W·x(t)+U·(r(t)⊙h(t−1)))
in the formula, W represents an input weight matrix of the candidate hidden layer state, U represents a transfer matrix of the candidate hidden layer state aiming at the hidden layer state of a former moment, and ⊙ represents a Hadamard product; and
the hidden layer state h(t) of the current moment is shown by:
h(t)=(1−z(t))⊙h(t−1)+z(t)⊙h̅(t).

5. The excimer laser energy model identification method according to claim 4, wherein
the output layer of the gated recurrent unit obtains the pulse energy E(t) of an excimer laser of a current moment according to the following formulas:
y(t)=σ(W_{y}·h(t))
E(t)=W_{E}·y(t)
in the formulas, y(t) represents an energy factor of the pulse energy of the current moment, W_{y} represents a weight matrix of the hidden layer state to the output layer, and W_{E} represents an output scale conversion coefficient.

6. The excimer laser energy model identification method according to claim 1, wherein
the training dataset is a mean value of the actual laser pulse energy in the same position under each corresponding laser burst mode at each discharge high voltage,
wherein at each discharge high voltage, all actual laser pulse energy under each corresponding laser burst mode is the actual laser pulse energy harvested after the energy harvesting conditions are set in the single laser pulse manner in a preset moment.

7. The excimer laser energy model identification method according to claim 1, wherein
a loss function of the gated recurrent unit network is as follows:
$$l = {\sum }_{t = 1}^{n} \frac{1}{2} {( {E}_{t} ( t ) - E ( t ) )}^{2}$$
in the formula, Eₜ(t) represents a mean value of the actual laser pulse energy in the same position under the laser burst mode at the discharge high voltage of a training sample at a current moment, E(t) represents a pulse energy sequence of the excimer laser output by the gated recurrent unit network, and n represents a specific moment.

8. The excimer laser energy model identification method according to claim 1, wherein the training the built gated recurrent unit network by using the training dataset comprises the following steps:
Step S31: randomly selecting one training sample from the training dataset, inputting the energy harvesting conditions corresponding to the mean value of all actual laser pulse energy in the training sample into the gated recurrent unit network one by one so that a pulse energy sequence under one burst mode is obtained through gated recurrent unit network training;
Step S32: calculating a loss function of the gated recurrent unit network corresponding to the currently selected training sample, and updating training parameters of the gated recurrent unit network according to the loss function;
Step S33: calculating an error between the pulse energy sequence under the burst mode currently output by the gated recurrent unit network and the current training sample; and
Step S34: circularly executing Steps S31 to S33, and ending the training to obtain the excimer laser energy model till reaching the training ending condition.

9. The excimer laser energy model identification method according to claim 8, wherein
the training ending condition of the gated recurrent unit network is the number of preset training times, or the number of preset times of circularly executing Steps S31 to S33, and the maximum error between each pulse energy in the pulse energy sequence under the burst mode output by the gated recurrent unit network in each time and the pulse energy in the same position in the training sample is smaller than 0.15 mJ.

10. An excimer laser energy model identification apparatus, comprising a processor and a memory, wherein the processor reads a computer program or instruction in the memory, and is configured to execute the following operations:
building a gated recurrent unit network for excimer laser energy model identification, and determining its input variable;
setting energy harvesting conditions in a single laser pulse manner in a plurality of preset moments to harvest a training dataset for excimer laser energy model identification; and
training the built gated recurrent unit network by using the training dataset, and ending the training to obtain an excimer laser energy model when reaching a training ending condition.
